(19) United States
(12) Patent Application Publication
(10) Pub. No.: US 2004/0163701 A1
(43) Pub. Date: Aug. 26, 2004

(54) Solar battery

(76) Inventor: Hideo Katayama, Tokyo (JP)

Correspondence Address: HOGAN & HARTSON L.L.P., 500 S. GRAND AVENUE, SUITE 1900, LOS ANGELES, CA, 90071-2611, US

(21) Appl. No.: 10/371,522

(22) Filed: Feb. 21, 2003

(51) Int. Cl. H01L 31/00

(52) U.S. Cl. 136/264; 438/95

(57) ABSTRACT

To minimize the limitations in the prior art, and to minimize other limitations that will become apparent upon reading and understanding the present specification, the present invention discloses a method and apparatus for an increased efficiency solar battery that is not as susceptible to temperature effects.

### BACKGROUND OF THE INVENTION

1. Field of the Invention

The present invention relates in general to power sources, and in particular to a solar battery that is less affected by temperature variations.

2. Description of the Related Art

Solar power sources, often called solar cells or solar batteries, have been used for many years. Typically, a solar batter is a p-n junction material, usually silicon, that is used to provide power to other circuits and devices.

However, solar batteries have a weakness in that the power output from such solar batteries varies with temperature. As additional sunlight strikes the surface of the solar battery, the efficiency of the solar battery decreases, and, as a result, the solar battery produces less current and/or less voltage at the output terminals.

For example, if the temperature is increased 10° C. on the surface of a solar battery, the electrical output decreases by 5%. As such, when solar batteries are used in applications where the temperature can vary by 10 degrees, the battery must be oversized to account for this variance. If solar batteries are used in an application that can vary by 40° C., the corresponding 20% decrease in output power may require additional backup power or force designers to use alternative power sources. If a solar battery is used, there may be occasions or situations where the battery is subjected to various heating from the sun and cannot produce the required power output.

It can be seen, then, that there is a need in the art for a solar battery that has increased energy conversion efficiency from solar energy. It can also be seen that there is a need in the art for a solar battery that does not suffer from temperature effects as do batteries of the related art.

### SUMMARY OF THE INVENTION

To minimize the limitations in the prior art, and to minimize other limitations that will become apparent upon reading and understanding the present specification, the present invention discloses a method and apparatus for an increased efficiency solar battery that is not as susceptible to temperature effects.

Claim 1

It is an object of the present invention to provide a solar battery that has increased energy conversion efficiency from solar energy. It is another object of the present invention to provide a solar battery that does not suffer from temperature effects as do batteries of the related art.

### BRIEF DESCRIPTION OF THE DRAWINGS

Referring now to the drawings in which like reference numbers represent corresponding parts throughout:

FIG. 1 is a cross-section of a solar battery by a compound semiconductor material of the present invention; and

FIG. 2 illustrates a front view of the vaporizer for vaporizing a compound semiconductor material in accordance with the present invention.

### DETAILED DESCRIPTION OF THE DRAWINGS

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

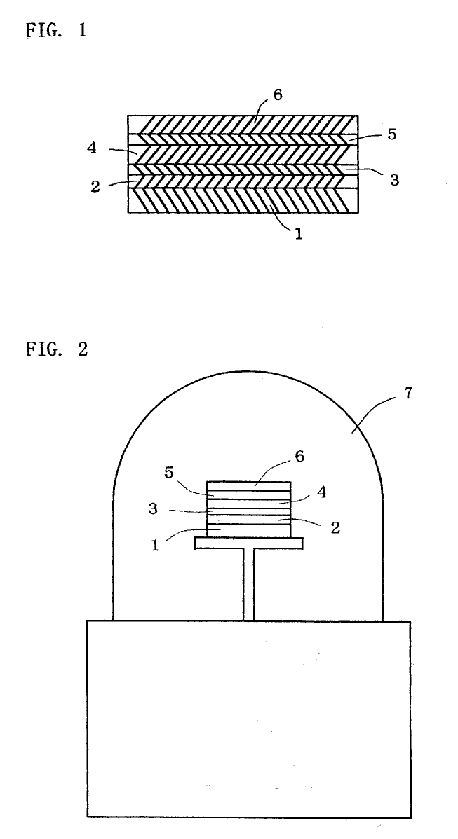

FIG. 1 is a cross-section of a solar battery by a compound semiconductor material of the present invention. As shown in FIG. 1, the solar battery of the present invention comprises an electrical insulator 1, a bottom contact layer 2, an n-type layer 3, a p-type layer 4, an n-type layer 5, and a p-type contact layer 6. These layers are deposited using a vaporizer 7 shown in FIG. 2.

Insulator 1 is typically a ceramic material, although insulator 1 can be other materials as long as the material used provides electrical insulation for the overall device. Preferably, the insulator 1 will provide insulation qualities for a 150° C. surface temperature when the device is illuminated by the sun, or the device is exposed to other thermal or optical radiation.

Bottom contact layer 2 is typically pure copper, with a purity of 99.00% or greater. However, bottom contact layer 2 can be other conductive materials such as aluminum, silver, gold, or other conductive materials without departing from the scope of the present invention. The bottom contact layer 2 is typically deposited on insulator 1 by vapor deposition, however, sputtering, molecular beam epitaxy, metal-oxide chemical vapor deposition (MOCVD), or other deposition techniques can be used if desired. The thickness of bottom contact layer 2 is typically between 200-400 microns thick, but can be thicker or thinner as desired.

N-type layer 3 is then deposited onto bottom contact layer through 2. N-type layer 3 is typically deposited onto bottom contact layer 2 by vapor deposition, however, sputtering, molecular beam epitaxy, metal-oxide chemical vapor deposition (MOCVD), or other deposition techniques can be used if desired.

N-type layer 3 is typically a tellurium (Te) indium (In) compound, and is typically made from 5N (99.9999% or greater purity) In and 6N (99.999999% or greater purity) Te. The mixture ratio between the In and Te is typically 5-30% In and 70-95% Te, where the ratio is determined by the application or desires of the designer. Other elements and other purity levels of the elements listed herein can be used for any layer 2-6 without departing from the scope of the present invention. N-type layer 3 is typically 100-200 microns thick, but can be thicker or thinner if desired or needed for the application of the device.

P-type layer 4 is then deposited onto n-type layer 3. P-type layer 4 is typically deposited onto n-type layer 3 by vapor deposition, however, sputtering, molecular beam epitaxy, metal-oxide chemical vapor deposition (MOCVD), or other deposition techniques can be used if desired. P-type layer 4 is typically a 6N Te film, but can be other elements, mixtures of elements or other purity levels as desired. P-type layer 4 is typically deposited with a thickness of 200-400 microns, but can be thicker or thinner but can be thicker or thinner if desired or needed for the application of the device.

N-type layer 5 is then deposited onto p-type layer 4. N-type layer 5 is typically deposited onto p-type layer 4 by vapor deposition, however, sputtering, molecular beam epitaxy, metal-oxide chemical vapor deposition (MOCVD), or other deposition techniques can be used if desired. N-type layer 5 is typically a mixture of Cadmium (Cd) and Te, where the Cd is typically of 5N purity or greater, and the Te is typically of 6N purity or greater. The composition of n-type layer 5 is typically between 5 and 50% Cd, but can be other compositions if desired. N-type layer 5 can be other elements, mixtures of elements or other purity levels as desired. N-type layer 5 is typically deposited with a thickness of 100-200 microns, but can be thicker or thinner but can be thicker or thinner if desired or needed for the application of the device.

P-type contact layer 6 is then deposited onto n-type layer 5. p-type contact layer 6 is typically deposited onto n-type layer 5 by vapor deposition, however, sputtering, molecular beam epitaxy, metal-oxide chemical vapor deposition (MOCVD), or other deposition techniques can be used if desired. P-type contact layer 6 is typically an indium tin oxide (ITO) compound, where the In is typically 3N purity or greater. The composition of p-type contact layer 6 is typically between 1 and 30% Tin oxide, but can be other compositions if desired. P-type contact layer 6 can be other elements, mixtures of elements or other purity levels as desired. P-type contact layer 6 is typically deposited with a thickness of 200-400 microns, but can be thicker or thinner but can be thicker or thinner if desired or needed for the application of the device.

P-type contact layer 6, when made from ITO, is a transparent electrode which allows the solar energy to pass through p-type contact layer 6 and activate the battery by generating a positive voltage. This positive voltage generated in p-type contact layer 6 generates a hole current, which excites a current in the n-type layer 5, which in turn excites a current in the p-type layer 4.

The current density in p-type layer 4 changes in proportion to the thermal temperature from the sun, and this current, when applied to n-type layer 3, generates an electron current that passes to copper film 2, which acts as the negative electrode of the device.

When struck with photonic energy from the sun, the ITO film 6 and copper film 2 act as the electrodes of the battery, which has elements of positive and negative films inbetween. When constructed as described herein, the increase in thermal energy in p-type layer 4 changes in proportion to the thermal energy, and saturates at a temperature of approximately 150 degrees Centigrade. As such, increases in solar energy will increase the output of the resultant device, rather than degrade similar devices in the related art.

Tellurium is used for the pn junctions, and used to access the contact layer 2 and p-type contact layer 6 because the resistance between these layers and the internal resistance of the Te layers decreases with a rise in temperature. This inversely proportional relationship, along with the decreased internal thermal losses, increases the current characteristics for the solar battery elements made using the present invention. As an example, at 50 degrees C., the generated voltage is 20 mV and the generated current is 50 mA per 5 mm² area of solar battery. As such, the solar battery of the present invention has an increasing current, rather than a decreasing current, as incident energy and resultant temperature increases.

FIG. 2 illustrates a front view of the vaporizer for vaporizing a compound semiconductor material in accordance with the present invention.

Vaporizer 7 is typically a vapor deposition device for deposition of the layers 2-6 described above. However, sputtering, molecular beam epitaxy, metal-oxide chemical vapor deposition (MOCVD), or other deposition devices can be used if desired without departing from the scope of the present invention.

### CONCLUSION

The foregoing description of the preferred embodiment of the invention has been presented for the purposes of illustration and description. It is not intended to be exhaustive or to limit the invention to the precise form disclosed. Many modifications and variations are possible in light of the above teaching. It is intended that the scope of the invention not be limited by this detailed description, but by the claims appended hereto.

What is claimed is:

1. A solar battery, comprising:
a first electrode coupled to an insulating layer;
a first n-type layer coupled to the first electrode;
a first p-type layer coupled to the first n-type layer, wherein the first p-type layer comprises at least tellurium;
a second n-type layer coupled to the first p-type layer; and
a second p-type layer, coupled to the second n-type layer, wherein the second p-type layer is used as a second electrode.

2. The solar battery of claim 1, wherein the second p-type layer comprises Indium Tin Oxide (ITO).

3. The solar battery of claim 2, wherein a material for the first electrode is selected from a group comprising: copper, gold, and silver.

4. The solar battery of claim 3, wherein the first n-type layer is indium telluride (InTe).

5. The solar battery of claim 4, wherein the second n-type layer is cadmium telluride (CdTe).

6. The solar battery of claim 5, wherein the first p-type layer is 99.999999% or greater purity Tellurium.

7. The solar battery of claim 6, wherein the first p-type layer has a thickness between 200 and 400 microns.

8. The solar battery of claim 7, wherein the first n-type layer has a thickness between 100 and 200 microns.

9. The solar battery of claim 8, wherein the first n-type layer has a composition of between 5 and 30 percent indium.

10. The solar battery of claim 9, wherein the second n-type layer has a composition of between 5 and 50 percent cadmium.

11. The solar battery of claim 10, wherein the second n-type layer has a thickness of between 100 and 200 microns.

12. The solar battery of claim 11, wherein the second p-type layer has a thickness of between 200 and 400 microns.

13. The solar battery of claim 12, wherein the second p-type layer has a composition of between 1 and 30 percent indium.

14. The solar battery of claim 13, wherein the indium in the second p-type layer has a purity of at least 99.999%.

15. A method for making a solar battery, comprising:
depositing a first electrode on an insulating layer;
depositing a first n-type layer on the first electrode;
depositing a first p-type layer on the first n-type layer, wherein the first p-type layer comprises at least tellurium;
depositing a second n-type layer on the first p-type layer; and
depositing a second p-type layer on the second n-type layer, wherein the second p-type layer is used as a second electrode.

16. The method of claim 15, wherein the depositing is performed using vapor deposition.
